(19) United States
(12) Patent Application Publication
(10) Pub. No.: US 2025/0266357 A1
(43) Pub. Date: Aug. 21, 2025

(54) DESIGNING ULTRALOW-DIELECTRIC-CONSTANT MATERIALS BY DOPING AMORPHOUS BORON NITRIDE

(71) Applicant: SAMSUNG ELECTRONICS CO., LTD., Suwon-si (KR)

(72) Inventors: Yongwoo SHIN, Concord, MA (US); Ali Hamze, Dorchester, MA (US); Valentina Lacivita, Cambridge, MA (US)

(73) Assignee: SAMSUNG ELECTRONICS CO., LTD., Suwon-si (KR)

(21) Appl. No.: 18/912,183

(22) Filed: Oct. 10, 2024

Related U.S. Application Data
(60) Provisional application No. 63/553,978, filed on Feb. 15, 2024.

(51) Int. Cl. H01L 23/532; C01B 21/064

(52) U.S. Cl. CPC H01L 23/5329; C01B 21/0648; C01P 2002/02; C01P 2002/54; C01P 2006/40

(57) ABSTRACT

A doped amorphous boron nitride film includes amorphous boron nitride and a dopant, wherein the dopant comprises K, Ba, Sr, Rb, Sc, Na, In, or La. In one embodiment, the doped amorphous boron nitride film has (i) a stable configuration as measured by energy above the convex hull (i.e., less than 100 meV per atom above the convex hull), (ii) an energy above hull that is lower in an amorphous phase than in a crystalline phase, and (iii) a dielectric constant that is below 4. A method for stabilizing an amorphous boron nitride film includes doping an amorphous boron nitride film with a dopant comprising K, Ba, Sr, Rb, Sc, Na, In, or La.

### CROSS-REFERENCE TO RELATED APPLICATION

This application is based on and claims priority from U.S. Provisional Application No. 63/553,978 filed on Feb. 15, 2024 in the U.S. Patent and Trademark Office, the disclosure of which is incorporated herein by reference in its entirety.

### BACKGROUND

### 1. Field

Materials according to embodiments relate to doped amorphous boron nitride films, and other embodiments relate to methods for stabilizing amorphous boron nitride films.

### 2. Description of the Related Art

Advancements in modern semiconductor devices have been driven by process and materials improvements that enable ever-greater transistor densities. However, resistance-capacitance delay has a critical issue for increasing transistor density and reducing the dimension of metal interconnect. Therefore, new materials with lower resistance and capacitance are needed to offset the negative effect of increasing resistance-capacitance delay on chip performance. Ultralow dielectric materials offer a way to overcome these obstacles since they can prevent quantum tunneling.

An IEEE International Roadmap for Devices and Systems (IRDS) roadmap for low-k dielectrics in metal-oxide-semiconductor field-effect transistors (MOSFETs) is shown in FIG. 1, a low-k dielectric in a copper interconnect is shown in FIG. 2, and an IRDS roadmap for low-k dielectrics in interconnects is shown in FIG. 3. Rsd in FIG. 1 is the resistance/micron of MOSFET width. In particular, per Note [5] in the IRDS roadmap, Rsd is the total parasitic series resistance (source plus drain) per micron of MOSFET width; these values include all components such as an accumulation layer, spreading resistance, sheet resistance, and contacts, and it is assumed that there is a 5% improvement per node cycle (2 years or 3 years).

The current state of the art material includes porous SiCOH (p-SiCOH). The pores reduce the dielectric constant, but do so at the cost of structural stability and increasing likelihood of dielectric breakdown and ionic diffusion through the dielectric.

Current state-of-the-art technology includes introducing fluorine or CH₃ in SiO₂ (collectively referred to as SiCOH) to achieve a relatively low dielectric constant, i.e., κ=3.7 for SiOF and κ=2.4˜2.8 for SiCOH against κ=4 of SiO₂. As shown in FIG. 4, p-SiCOH further reduces the dielectric constant relative to SiCOH by introducing pores (k=1). However, this comes at the cost of structural stability as shown in FIG. 5 and increasing likelihood of dielectric breakdown and ionic diffusion through the dielectric.

Amorphous boron nitride (aBN) is a strong candidate for achieving ultralow-dielectric-constant. That is, amorphous boron nitride (aBN) is a promising new low-k dielectric material for future devices that has been synthesized with a dielectric constant ˜2 (beyond IRDS road map targets). However, it is not easy to decrease the dielectric constant; indeed, the dielectric constant of aBN increases when the film grows thicker, likely due to increased crystallization as the films thicken.

Thus, there is a need for ultralow-dielectric-constant materials that overcome the problems discussed above.

Information disclosed in this Background section has already been known to the inventors before achieving the disclosure of the present application or is technical information acquired in the process of achieving the disclosure. Therefore, it may contain information that does not form the prior art that is already known to the public.

### SUMMARY

In the present disclosure, candidate dopants were found that prevent crystallization of amorphous BN. Therefore, the candidate dopants keep the structure's dielectric-constant ultralow when the film grows thicker than the critical width (e.g., thicker than 3 nm in some embodiments, or thicker than 5 nm in other embodiments, or thicker than 10 nm in still other embodiments).

In particular, K, Ba, Sr, Rb, Sc, Na, In, and La are candidate dopants for stabilizing the amorphous phase and destabilizing the crystal phase.

The materials in this disclosure are newly discovered dopants for amorphous BN, which can stabilize the amorphous phase and destabilize the crystal phase. Therefore, a thick film of ultralow-dielectric-constant materials can be synthesized following this disclosure.

Advantages of this disclosure include that one can synthesize ultralow-dielectric-constant materials according to this disclosure by doping amorphous BN that can be used as diffusion barriers against electro-migration from an interconnect in the next-generation semiconductor. The dielectric constant of aBN is competitive with that of p-SiCOH, but aBN does not have pores and so does not have the drawbacks that come with them. Therefore, by doping aBN to prevent crystallization, it can replace p-SICOH as a low-k dielectric with greater mechanical stability, reduced chance of dielectric breakdown, and no ionic diffusion through it.

A first embodiment of the present disclosure provides a doped amorphous boron nitride film comprising amorphous boron nitride and a dopant, wherein the dopant comprises K, Ba, Sr, Rb, Sc, Na, In, or La.

A second embodiment of the present disclosure provides a doped amorphous boron nitride film of the first embodiment, wherein the dopant comprises K.

A third embodiment of the present disclosure provides a doped amorphous boron nitride film of the first embodiment, wherein the dopant comprises Ba.

A fourth embodiment of the present disclosure provides a doped amorphous boron nitride film of the first embodiment, wherein the dopant comprises Sr.

A fifth embodiment of the present disclosure provides a doped amorphous boron nitride film of the first embodiment, wherein the dopant comprises Rb.

A sixth embodiment of the present disclosure provides a doped amorphous boron nitride film of the first embodiment, wherein the dopant comprises Sc.

A seventh embodiment of the present disclosure provides a doped amorphous boron nitride film of the first embodiment, wherein the dopant comprises Na.

An eighth embodiment of the present disclosure provides a doped amorphous boron nitride film of the first embodiment, wherein the dopant comprises In.

A ninth embodiment of the present disclosure provides a doped amorphous boron nitride film of the first embodiment, wherein the dopant comprises La.

A tenth embodiment of the present disclosure provides a doped amorphous boron nitride film of the first embodiment, wherein the doped amorphous boron nitride film has (i) a stable configuration as measured by energy above the convex hull (defined as less than 100 meV per atom above the convex hull), (ii) an energy above hull that is lower in an amorphous phase than in a crystalline phase, and (iii) a dielectric constant that is below 4. Another embodiment provides a doped amorphous boron nitride film of the tenth embodiment, wherein the dielectric constant is 2 or less.

An eleventh embodiment of the present disclosure provides a doped amorphous boron nitride film of the first embodiment, wherein the doped amorphous boron nitride film has (i) a meta-stable configuration as measured by energy above the convex hull (defined as less than 250 meV per atom above the convex hull), (ii) an energy above hull that is lower in an amorphous phase than in a crystalline phase, and (iii) a dielectric constant that is below 4. Another embodiment provides a doped amorphous boron nitride film of the eleventh embodiment, wherein the dielectric constant is 2 or less.

A twelfth embodiment of the present disclosure provides a method for stabilizing an amorphous boron nitride film, comprising doping an amorphous boron nitride film with a dopant comprising K, Ba, Sr, Rb, Sc, Na, In, or La.

A thirteenth embodiment of the present disclosure provides a method for stabilizing an amorphous boron nitride film of the twelfth embodiment, wherein the dopant comprises K.

A fourteenth embodiment of the present disclosure provides a method for stabilizing an amorphous boron nitride film of the twelfth embodiment, wherein the dopant comprises Ba.

A fifteenth embodiment of the present disclosure provides a method for stabilizing an amorphous boron nitride film of the twelfth embodiment, wherein the dopant comprises Sr.

A sixteenth embodiment of the present disclosure provides a method for stabilizing an amorphous boron nitride film of the twelfth embodiment, wherein the dopant comprises Rb.

A seventeenth embodiment of the present disclosure provides a method for stabilizing an amorphous boron nitride film of the twelfth embodiment, wherein the dopant comprises Sc.

An eighteenth embodiment of the present disclosure provides a method for stabilizing an amorphous boron nitride film of the twelfth embodiment, wherein the dopant comprises Na.

A nineteenth embodiment of the present disclosure provides a method for stabilizing an amorphous boron nitride film of the twelfth embodiment, wherein the dopant comprises In.

A twentieth embodiment of the present disclosure provides a method for stabilizing an amorphous boron nitride film of the twelfth embodiment, wherein the dopant comprises La.

### BRIEF DESCRIPTION OF DRAWINGS

The patent or application file contains at least one drawing executed in color. Copies of this patent or patent application publication with color drawing(s) will be provided by the Office upon request and payment of the necessary fee.

Example embodiments of the present disclosure will be more clearly understood from the following detailed description taken in conjunction with the accompanying drawing in which:

FIG. 1 shows an IRDS roadmap for low-k dielectrics in MOSFETs.

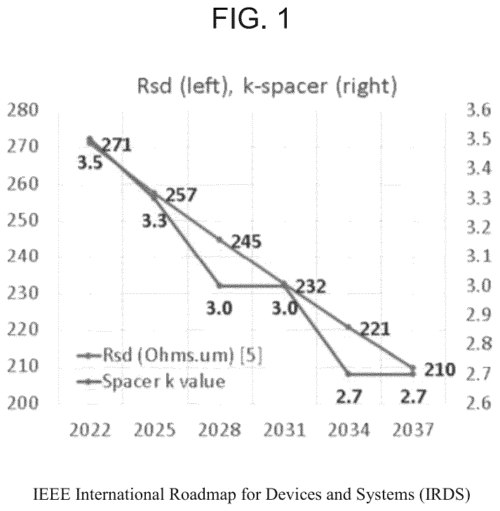

FIG. 2 shows a low-k dielectric in a copper interconnect.

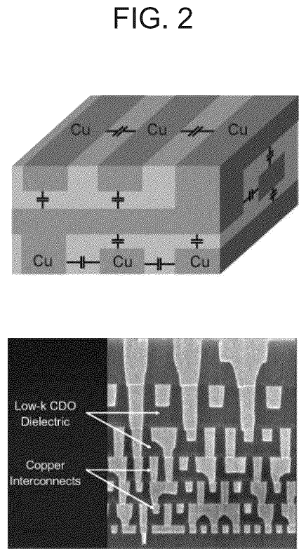

FIG. 3 shows an IRDS roadmap for low-k dielectrics in interconnects.

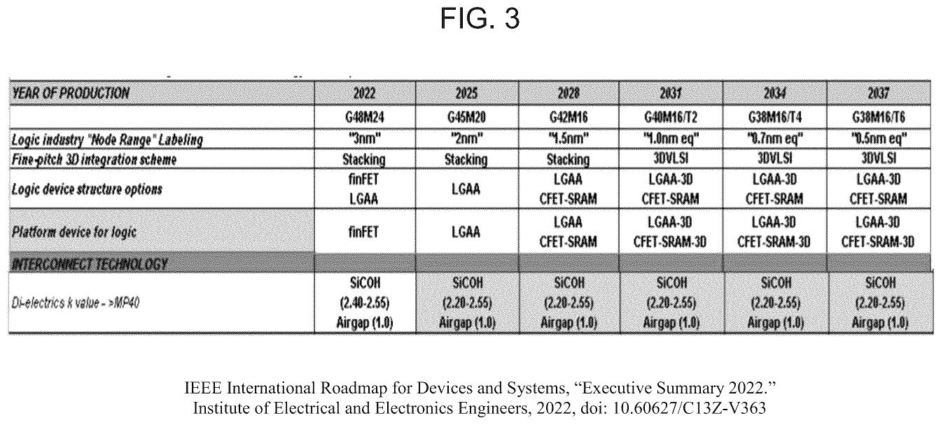

FIG. 4 shows p-SiCOH, in which pores have been introduced into SICOH.

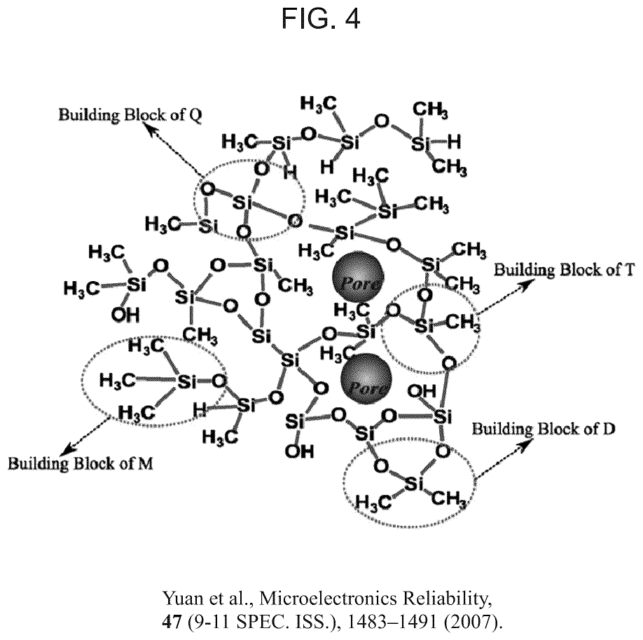

FIG. 5 is a graph showing mechanical instability as porosity increases.

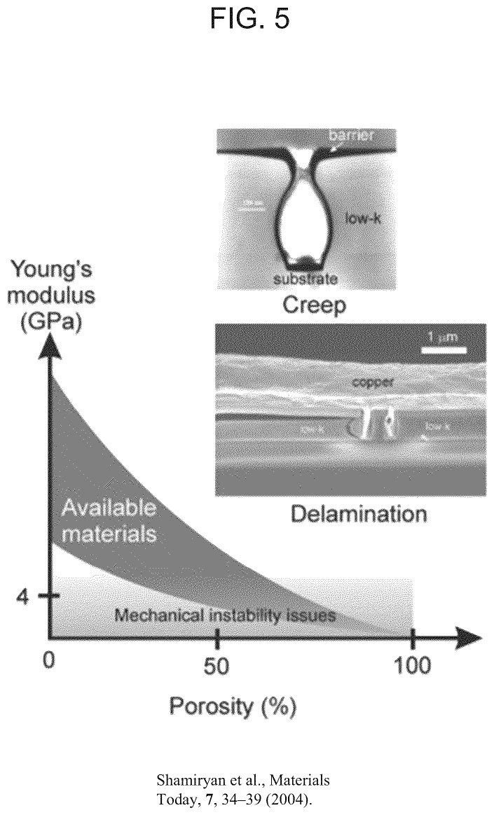

FIG. 6 is a flowchart showing the screening procedure to find candidate dopants for stabilizing amorphous boron nitride and destabilizing crystal phases.

FIG. 7A is an illustration of a doped hBN structure, FIG. 7B is an illustration of a doped cBN structure, and FIG. 7C is an illustration of a doped aBN structure.

FIG. 8 is an graphical representation of calculation results vs. the candidate list by relative Eₕᵤₗₗ screening.

FIG. 9 is an graphical representation of dielectric constant calculation results vs. the candidate list.

FIG. 10 shows an exemplary invention of amorphous BN doped with potassium and the energies above hull and dielectric constants resulting from doping with varying concentrations of potassium.

### DETAILED DESCRIPTION OF EXAMPLE EMBODIMENTS

In this disclosure, candidate dopants were found that stabilize amorphous boron nitride (BN) and destabilize crystal phases. Therefore, the candidate dopants keep the BN structure ultralow-dielectric-constant when the film grows thicker than the critical width.

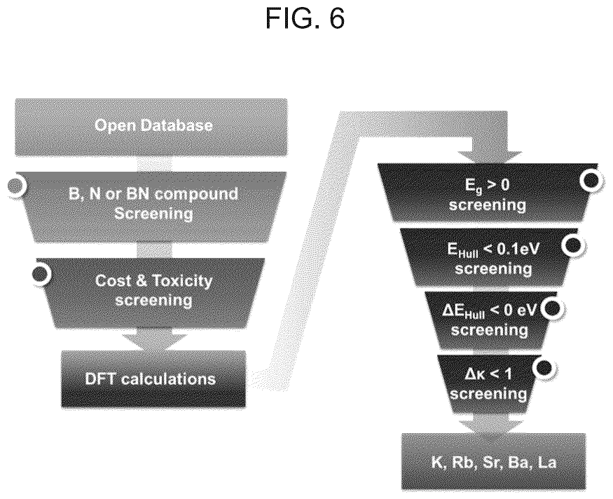

To find the candidate dopants, a screening procedure as shown in FIG. 6 and discussed below was used.

An open database was screened for all possible elements which can synthesize stable structures with boron, nitride, or boron-nitride.

All toxic materials and high-cost elements were removed, and then 24 candidates were selected.

Atomic structures of hexagonal BN (hBN), cubic BN (cBN), and three amorphous BNs (aBN) were generated using the first-principles Density Functional Theory (DFT).

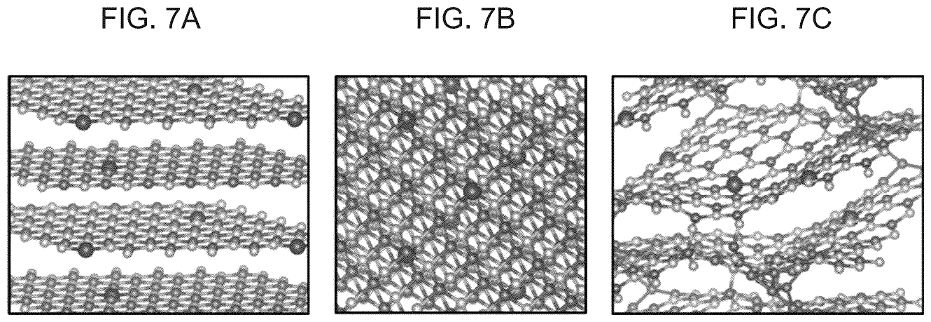

All five (5) structures were doped by 24 candidate elements with 1˜2% of doping ratio and calculated by DFT to get energy and electronic structures. Doped structures are shown in FIGS. 7A-7C, with FIG. 7A being an illustration of a doped hBN structure, FIG. 7B being an illustration of a doped cBN structure, and FIG. 7C being an illustration of a doped aBN structure.

Particular dopants were excluded that change the entire electronic structure to the metallic, i.e., Energy bandgap=0 eV.

Energy above the convex hull (Eₕᵤₗₗ) was calculated, and Eₕᵤₗₗ<0.1 eV was selected to find dopable elements.

Eₕᵤₗₗ was compared between aBN and hBN with following equation (1):

$$Δ {E}_{Hull} = ave ( {E}_{Hull}^{Doped} ( aBN ) ) - {E}_{Hull}^{Doped} ( hBN ) \qquad equation ( 1 )$$

and 6 candidate dopants were screened: K, Rb, Sr, Zr, Ba, and La.

Dielectric constant variation by doping was then calculated. Finally, 5 candidate dopants were screened: K, Rb, Sr, Ba, and La.

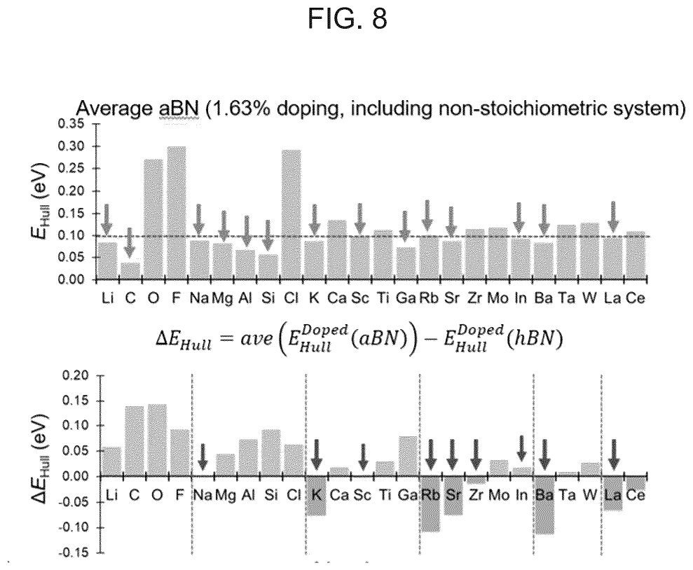

In particular, the calculation results for the candidate list by relative Eₕᵤₗₗ screening are shown in FIG. 8. In the top part of FIG. 8, the calculation results of Eₕᵤₗₗ for 24 dopants are shown, with the red dashed line representing 100 meV. In the bottom part of FIG. 8, calculation of the Emil difference between aBN and hBN using equation (1) is shown, with blue negative values representing stabilizing amorphous phases and arrows showing the final candidate dopants.

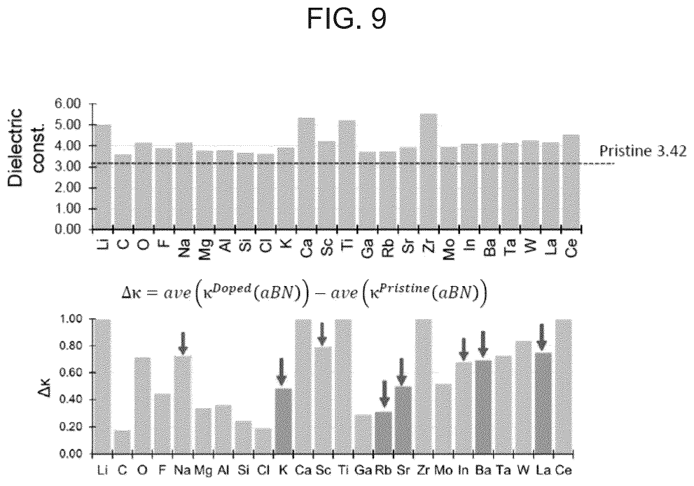

Further, the dielectric constant calculation results and the final candidate list are shown in FIG. 9. In the top part of FIG. 9, the average dielectric constants of doped aBN are shown, with the red dashed line representing the average dielectric constant of aBN, In the bottom part of FIG. 9, dielectric constant differences between doped aBN and pristine aBN are shown, with 8 candidate dopants being finally selected: K, Ba, Sr, Rb, Sc, Na, In, and La.

The doped amorphous boron nitride film of the present disclosure can be made by techniques known in the art, such as sputtering, chemical vapor deposition (CVD), plasma-enhanced chemical vapor deposition (PECVD), and atomic layer deposition (ALD). For example, the film can be made by inductively coupled PECVD conducted at 50-550° C. for 10-40 minutes using borazine precursor molecules. The doped amorphous boron nitride film of the present disclosure can be used as a low-k dielectric in modern semiconductor devices, such as a low-k dielectric in copper interconnects for MOSFETs. The doping stabilizes the amorphous phase of boron nitride and destabilizes the crystal phase, thereby permitting thicker amorphous boron nitride films with low dielectric constant to be formed.

### EXAMPLE

An embodiment will now be illustrated by way of the following example, which does not limit the disclosure in any way.

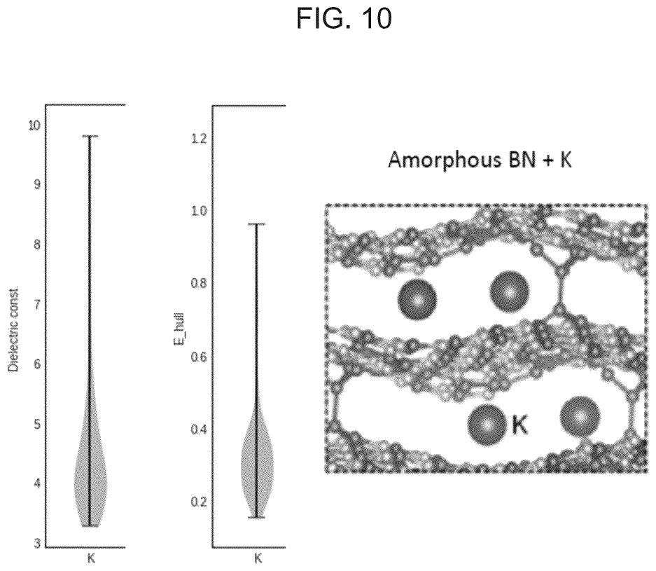

An exemplary embodiment of the present disclosure is shown in FIG. 10. In the right part of FIG. 10, potassium dopants in a-BN sit between sp²-coordinated layers that crystalline h-BN prefers to form, reducing the crystallinity and increasing the entropy of the system. In the middle part of FIG. 10, doping with varying concentrations of K does not result in very large energies above hull, indicating the doped amorphous structures are synthesizable. In the left part of FIG. 10, doping with varying concentrations of K does not result in large dielectric constants.

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

What is claimed is:

1. A doped amorphous boron nitride film comprising amorphous boron nitride and a dopant, wherein the dopant comprises K, Ba, Sr, Rb, Sc, Na, In, or La.

2. The doped amorphous boron nitride film according to claim 1, wherein the dopant comprises K.

3. The doped amorphous boron nitride film according to claim 1, wherein the dopant comprises Ba.

4. The doped amorphous boron nitride film according to claim 1, wherein the dopant comprises Sr.

5. The doped amorphous boron nitride film according to claim 1, wherein the dopant comprises Rb.

6. The doped amorphous boron nitride film according to claim 1, wherein the dopant comprises Sc.

7. The doped amorphous boron nitride film according to claim 1, wherein the dopant comprises Na.

8. The doped amorphous boron nitride film according to claim 1, wherein the dopant comprises In.

9. The doped amorphous boron nitride film according to claim 1, wherein the dopant comprises La.

10. The doped amorphous boron nitride film according to claim 1, which has (i) a stable configuration as measured by energy above convex hull, (ii) an energy above hull that is lower in an amorphous phase than in a crystalline phase, and (iii) a dielectric constant that is below 4.

11. The doped amorphous boron nitride film according to claim 1, wherein the doped amorphous boron nitride film has (i) a meta-stable configuration as measured by energy above convex hull, (ii) an energy above hull that is lower in an amorphous phase than in a crystalline phase, and (iii) a dielectric constant that is below 4.

12. A method for stabilizing an amorphous boron nitride film, comprising doping an amorphous boron nitride film with a dopant comprising K, Ba, Sr, Rb, Sc, Na, In, or La.

13. The method according to claim 12, wherein the dopant comprises K.

14. The method according to claim 12, wherein the dopant comprises Ba.

15. The method according to claim 12, wherein the dopant comprises Sr.

16. The method according to claim 12, wherein the dopant comprises Rb.

17. The method according to claim 12, wherein the dopant comprises Sc.

18. The method according to claim 12, wherein the dopant comprises Na.

19. The method according to claim 12, wherein the dopant comprises In.

20. The method according to claim 12, wherein the dopant comprises La.
